(19) United States
(12) Patent Application Publication
(10) Pub. No.: US 2009/0245995 A1
(43) Pub. Date: Oct. 1, 2009

(54) GAME SKID

(76) Inventors: Glenn Bielech, Grande Prairie (CA); Brad Neuls, Warman (CA)

Correspondence Address: STANDLEY LAW GROUP LLP, 6300 Riverside Drive, Dublin, OH, 43017, US

(21) Appl. No.: 12/409,596

(22) Filed: Mar. 24, 2009

(30) Foreign Application Priority Data
Mar. 31, 2008 (CA) 2627850

(51) Int. Cl. H01L 21/677; B60P 9/00; B60R 9/06

(52) U.S. Cl. 414/800; 414/462; 280/769

(57) ABSTRACT

A method and apparatus for transporting a game animal a hunter has killed or other large animal body is provided. The apparatus has a hitch bar attachable to a hitch receiver on a vehicle. A platform is connected to the hitch bar so that when the hitch bar is connected to a vehicle, the hitch bar alone supports the platform above the ground. For transporting an animal a hunter has killed, the head of the animal is secured onto the platform with the body of the animal extended behind the platform and lying on the ground. The animal can then be pulled by the vehicle, with the head supported above the ground by the platform and the body being pulled behind the platform along the ground.

### CROSS-REFERENCE TO RELATED APPLICATIONS

As authorized by 35 U.S.C. § 119, this application claims priority to and hereby incorporates by reference Canadian Application Serial No. 2,627,850, titled GAME SKID, filed on Mar. 31, 2008.

### TECHNICAL FIELD

This invention is in the field of methods and apparatus for transporting game a hunter has killed or other large dead animals and more particular a method and apparatus for skidding an animal along the ground behind a vehicle.

### BACKGROUND

Hunting often requires a hunter to range over a fair amount of distance in order to find game and frequently takes them far into the wilderness or other remote areas. Often when a hunter finds and kills an animal, the location does not allow the animal to be loaded onto a vehicle in the spot where it is killed. This may be because a vehicle suitable for long distance transport of the killed animal, such as a pickup truck, can not easily access the location where the animal is killed or if the animal is accessible by a pickup truck or other vehicle suitable for transporting the killed animal long distances, the surrounding terrain makes it is hard or impossible to load the killed animal onto or into the vehicle where it was killed. It is common for hunters to hunt alone and it is often very hard or even impossible for a single person or even two people to load a killed animal onto a vehicle for long distance transport. This is especially true when the hunter is hunting for big game animals such as elk, moose, etc. which can weight up to 1000 lbs or even more. If the loading location is not ideal, such as in bushy or a treed area, it may be impossible to load the animal onto or into the transport vehicle.

A hunter often has to move the killed animal to another area where the killed animal can be loaded into a vehicle for long distance transport or taken back to the hunter's camp. To transport the animal to another location, the animal is typically pulled or skidded along the ground. For smaller game animals and relatively short distances it is often possible for the hunter to manually drag the animal. However, if the killed animal needs to be transported a significant distance or the animal is a big game animal it may not be practical or even possible to manually drag the animal. Often, hunters will use a small personal vehicle such as an ATV or snowmobile to skid or drag the animal to the desired location. In some cases, if the location of the animal is accessible by a four wheel drive equipped truck, the animal can be tied to the truck and skidded or dragged along the ground behind the truck. To move the animal by skidding it behind a vehicle, typically, the hunter simply ties the animal to the vehicle and pulls it along the ground behind the vehicle.

Simply tying the animal behind a vehicle and dragging it along the ground creates some problems. For animals with antlers, the antlers can catch on obstacles or dig into the ground. Not only can this cause problems with the transporting of the animal, causing it to jerk and bounce around as it is dragged along the ground or even snagging the animal to such an extent that the rope tied to the animal breaks or the vehicle doing the pulling is stopped, but it can also damage the antlers. Most hunters try to avoid damaging the antlers of an animal because they are often considered a trophy of the hunt that the hunter would like to keep. There are even ranking schemes that allow a hunter to “score” his or her animal based on the antlers and for especially exemplary sets of antlers, the hunter often likes to keep the antlers as a trophy.

Additionally, often a hunter wants to save the antlers and head of killed animals for later mounting by a taxidermist. This is especially true with big game animals that a hunter does not often get to hunt or is hunting primarily for sport. Where the head of the animal is going to be mounted by a taxidermist, it is desirable to prevent any damage occurring to the antlers and cape of the animal.

### SUMMARY OF THE INVENTION

It is an object of the present invention to provide an apparatus and method for transporting a game animal relatively short distances that overcomes problems in the prior art.

In a first aspect, an apparatus for transporting a game animal is provided. The apparatus comprises a hitch bar attachable to a hitch receiver on a vehicle and a platform rigidly connected to the hitch bar such that when the hitch bar is connected to a hitch receiver of a vehicle, the platform is supported above a ground surface by the hitch bar alone. The platform is sized to accept a head of an animal such that when the head of the animal is secured to the top surface of the platform, at least a portion of a body of the animal rests on a ground surface behind the game skid.

In a second aspect, an apparatus for transporting a game animal is provided. The apparatus comprises a hitch bar attachable to a hitch receiver on a vehicle and a platform rigidly connected to the hitch bar and having a front portion and a back portion, the platform having a front portion and a back portion such that the front portion is supported substantially horizontally above a ground surface and the back portion is angled downwards towards a ground surface when the game skid is connected to a hitch receiver of a vehicle whereby when a head of an animal is secured to the front portion of the platform with a body of the animal positioned behind the game skid, the back portion of the platform will at least partially support a neck of the animal.

In a third aspect, a method of transporting a game animal behind a vehicle is provided. The method comprises; providing a platform connected to a hitch bar; connecting the hitch bar to a vehicle so that the hitch bar alone supports the platform above a ground surface; securing a head of the game animal onto the platform with the body of the animal extended behind the platform and lying on a ground surface; and pulling the animal with the vehicle, the head of the animal supported above the ground surface by the platform and the body of the animal dragging along the ground surface behind the platform.

In an aspect, a game skid is provided having a platform connectable to a hitch receiver on a vehicle by a hitch bar. When the hitch bar is connected to a hitch receiver on a vehicle, the hitch bar alone supports the platform above the ground. At the rear of the platform, the platform is angled downwards towards the ground.

To transport an animal a hunter has killed or another large dead animal using the game skid, a person lifts the head of the animal off of the ground and places it on the game skid. The head of the animal will fit on the platform but not the body of the animal. The body of the animal extends behind the platform and lies on the ground. The neck of the animal will be at least partially supported by the rear portion of the platform angled downwards toward the ground.

In this manner, because a killed animal can be quite heavy, a person only has to lift the head of the animal off of the ground in order to secure the animal to the game skid. This allows a single person to attach an animal to the game skid and transport the animal using the game skid.

### DESCRIPTION OF THE DRAWINGS

While the invention is claimed in the concluding portions hereof, preferred embodiments are provided in the accompanying detailed description which may be best understood in conjunction with the accompanying diagrams where like parts in each of the several diagrams are labeled with like numbers, and where:

FIG. 1 is perspective view of a game skid in an aspect;

FIG. 2 is a side view of the game side shown in FIG. 1;

FIG. 3 is a side view of the games skid shown in FIG. 1 attached to a hitch receiver on an ATV; and

FIG. 4 is a side view of an animal positioned in the game skid of FIG. 1 ready to be moved.

### DETAILED DESCRIPTION OF THE ILLUSTRATED EMBODIMENTS

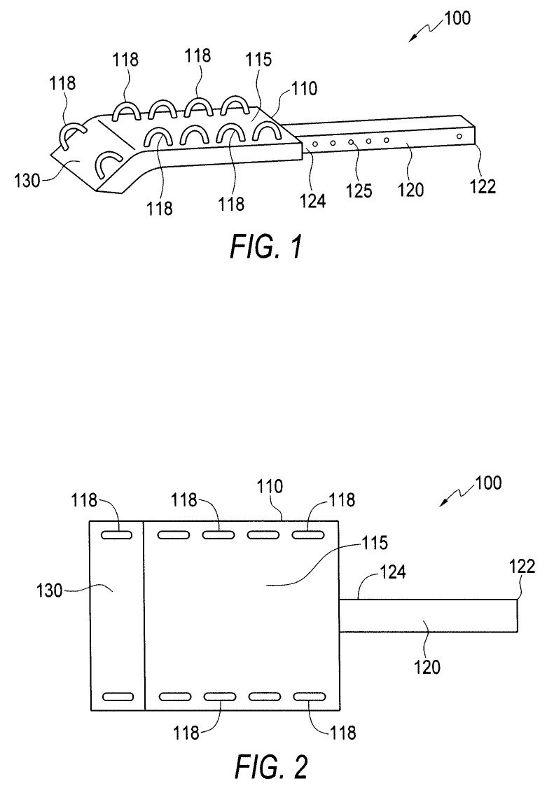

FIGS. 1 and 2 illustrate a game skid 100. The game skid 100 has a platform 110, for supporting the head of an animal when the game skid 100 is in use, and a hitch bar 120 to attach the game skid 100 to a vehicle.

The platform 110 has a front portion 115 sized to accept the head of a game animal such as a deer, moose, elk, etc. In an aspect, the front portion 115 is less than 2 ft wide and 2 ft long providing just enough space to hold a head of an animal with the body of the animal to rest on the ground behind the game skid 100. On each side of the front portion 115 of the platform 110, anchor points in the form of connection loops 118 are provided on the front portion 115 of the platform 110 along a periphery of the front portion 115 that allow a rope, tensioning strap or other tie down to be attached through the connection loops 118. A rear portion 130 of the platform 110 is angled downward towards the ground surface. The rear portion 130 will support a neck of an animal when the head of the animal is secured to the front portion 115 of the platform 110. Typically, the front portion 115 and the rear portion 130 of the platform 110 are joined and together form a continuous unobstructed surface. In one aspect, the rear portion 130 is angled downwards at an angle between 20° and 70° relative to the front portion and in a further aspect the rear portion 130 of the platform 110 is angled at approximately 45° downwards relative to the front portion 115 of the platform 110.

The hitch bar 120 allows the game skid 100 to be attached to a hitch receiver (not shown) of a vehicle such as four-wheel drive pickup, ATV, snowmobile, etc. The hitch bar 120 is connectable at a first end 122 to a hitch receiver on a vehicle (not shown). Typically, the hitch bar 120 has a square-cross-sectional area sized to slide inside the square cross-sectional area of a hitch receiver where a pin (not shown) is then used to secure the hitch bar 120 in the hitch receiver. When the hitch bar 120 is connected to a hitch receiver, the hitch bar 120 is rigidly connected to the hitch receiver such that it cannot move up/down or side-to-side relative to the hitch receiver. Depending on the height off of the ground a hitch receiver will be positioned at, the hitch bar 120 can be straight (as shown in FIG. 1) or it could be curved downwards or upwards to provide a proper height for the platform 110 allowing a body of an animal to rest on the ground surface when a head of the animal is secured on the platform 110.

The platform 110 is rigidly connected or attachable to a second end 124 of the hitch bar 120 so that when the hitch bar 120 is connected to a hitch receiver of a vehicle (not shown), the hitch bar 120 alone supports the platform 110 above a ground surface with the front portion 115 of the platform 110 supported in a substantially horizontal position from the ground surface and the rear portion 130 of the platform 110 angled towards the ground surface. In an aspect, a series of apertures 125 are provided in the hitch bar 120 that allow the platform 110 to be adjustable connected to the hitch bar 120 causing the distance of the platform 110 behind a vehicle to be varied.

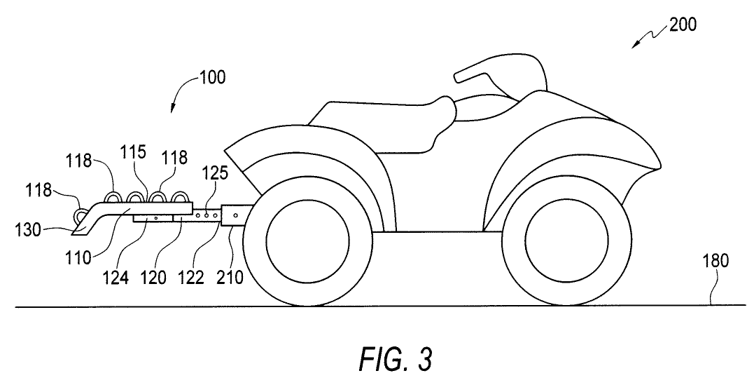

FIG. 3 illustrates the game skid 100 connected to a vehicle 200. In operation, game skid 100 is attachable to a hitch receiver 210 of a vehicle 200. The platform 110 is connected to the hitch bar 120 and the hitch bar 120 is connected to the hitch receiver 210 on the vehicle 200 so that the front portion 115 of the platform 110 is facing upwards and the platform 110 is suspended above a ground surface 180 by the hitch bar 120 alone.

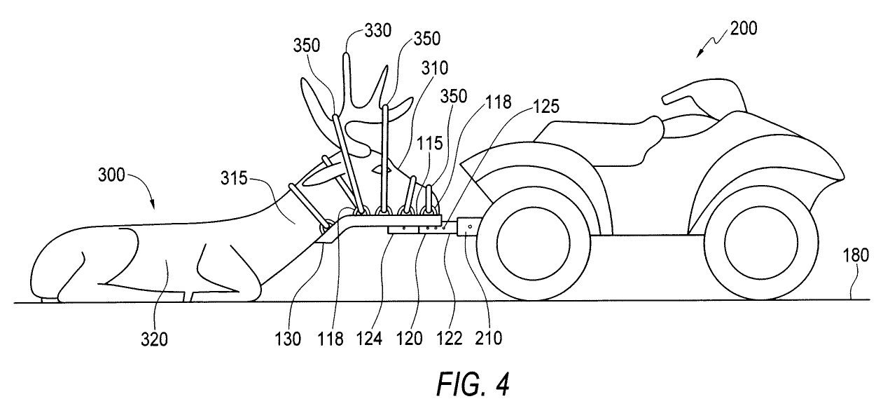

FIG. 4 illustrates an animal 300 secured to the game skid 100. The animal 300 is attached to the game skid 100 by placing the head 310 of the animal 300 on the front portion 115 of the platform 110 so that the head 310 of the animal 300 is supported above the ground surface 180 by the front portion of the platform 110 and the body 320 of the animal 300 is positioned behind the game skid 100 lying on the ground surface 180. In the case of antlered game animals, the head 310 of the animal 300 can be positioned on the platform 110 so that the antlers 330 extend upwards and away from the ground surface 180. The neck 315 of the animal 300 will typically lie on the back portion 130 of the platform 110 that is angled towards the ground surface 180 so that the back portion 130 supports at least a portion of the neck 315 of the animal 300. The head 310 of the animal 300 can be secured onto the game skid 100 by using rope 350 or other securing means to tie or secure the head 310 of the animal 300 against the front portion 115 of the platform 110. Typically, the rope 350 or other securing means used should circle behind the head and antlers 330 of the animal to prevent the head 310 of the animal 300 from sliding off of the back of the platform 110. With the head 310 of the animal 300 secured to the platform 110, a user can then drive the vehicle 200 with the head 310 of the animal 300 safely carried above the ground surface 180 and the body 320 of the animal 300 being dragged or skidded along the ground surface 180 behind the game skid 100.

In this manner, the game skid 100 only has to support the weight of the head 310 of the animal 300. The body 320 of the animal 300, having a much greater weight that the head 310, remains lying on the ground surface 180. To secure the animal 300 to the game skid 100, a person only has to lift up the head 310 of the animal 300, a relatively light part of the animal 300 to prepare the animal 300 for transport with the game skid 100. By supporting the head 310 of the animal 300 above the ground surface 180, damage to the head 310 (including the cape) and antlers 330 of the animal 300 is prevented and the animal 300 is more easily dragged because the head 310 is lifted above the ground surface 180 and out of the way of obstacles.

The foregoing is considered as illustrative only of the principles of the invention. Further, since numerous changes and modifications will readily occur to those skilled in the art, it is not desired to limit the invention to the exact construction and operation shown and described, and accordingly, all such suitable changes or modifications in structure or operation which may be resorted to are intended to fall within the scope of the claimed invention.

What is claimed is:

1. An apparatus for transporting a dead animal, the apparatus comprising
a hitch bar attachable to a vehicle; and
a platform rigidly connected to the hitch bar such that when the hitch bar is connected to a vehicle, the platform is supported above a ground surface by the hitch bar alone,
wherein the platform is sized to accept a head of an animal such that when the head of the animal is secured to the top surface of the platform, at least a portion of a body of the animal rests on a ground surface adjacent the game skid.

2. The apparatus of claim 1 wherein the hitch bar is attachable to a vehicle by being attachable to a hitch receiver on the vehicle.

3. The apparatus of claim 2 wherein the platform has a front portion and a back portion and wherein when the game skid is connected to a hitch receiver of a vehicle, the front portion is supported substantially horizontally above a ground surface and the back portion is angled downwards towards a ground surface and wherein when a head of an animal is secured to the front portion of the platform with a body of the animal positioned behind the game skid, the back portion of the platform will at least partially support a neck of the animal.

4. The apparatus of claim 3 wherein the back portion of the platform is angled between 20° and 70° downwards relative to the front portion.

5. The apparatus of claim 4 wherein the back portion of the platform is angled at substantially 45° downwards relative to the front portion.

6. The apparatus of claim 3 wherein the front portion of the platform has an unobstructed transition to the back portion of the platform.

7. The apparatus of claim 3 wherein the platform has anchor points at least on a periphery of the front portion of the platform.

8. The apparatus of claim 7 wherein the anchor points are connection loops.

9. The apparatus of claim 2 wherein the hitch bar is removably connectable to a hitch receiver.

10. The apparatus of claim 1 wherein the platform is removably connectable to the hitch bar.

11. The apparatus of claim 10 wherein the hitch bar has a number of apertures passing through the hitch bar, allowing a length of the hitch bar to be adjusted.

12. The apparatus of claim 1 wherein the hitch bar is straight.

13. An apparatus for transporting a dead animal, the apparatus comprising
a hitch bar attachable to a hitch receiver on a vehicle; and
a platform rigidly connected to the hitch bar and having a front portion and a back portion, the platform having a front portion and a back portion such that the front portion is supported substantially horizontally above a ground surface and the back portion is angled downwards towards a ground surface when the game skid is connected to a hitch receiver of a vehicle whereby when a head of an animal is secured to the front portion of the platform with a body of the animal positioned behind the game skid, the back portion of the platform will at least partially support a neck of the animal.

14. The apparatus of claim 13 wherein the back portion of the platform is angled between 20° and 70° downwards relative to the front portion.

15. The apparatus of claim 14 wherein the back portion of the platform is angled at substantially 45° downwards relative to the front portion.

16. A method of transporting a dead animal behind a vehicle, the method comprising;
providing a platform connected to a hitch bar;
connecting the hitch bar to a vehicle so that the hitch bar alone supports the platform above a ground surface;
securing a head of the game animal onto the platform with the body of the animal extended behind the platform and lying on a ground surface; and
pulling the animal with the vehicle, the head of the animal supported above the ground surface by the platform and the body of the animal dragging along the ground surface behind the platform.

17. The method of claim 16 wherein the platform has a front portion and a back portion and wherein when the game skid is connected to a hitch receiver of a vehicle, the front portion is supported substantially horizontally above a ground surface and the back portion is angled downwards towards a ground surface and wherein when the head of an animal is secured to the front portion of the platform with the body of the animal positioned behind the game skid, the back portion of the platform will at least partially support the neck of the animal.
